(19) United States
(12) Patent Application Publication
(10) Pub. No.: US 2025/0294685 A1
(43) Pub. Date: Sep. 18, 2025

(54) SUBSTRATE WITH BURIED GLASS CORE

(71) Applicant: QUALCOMM Incorporated, San Diego, CA (US)

(72) Inventors: Hong Bok WE, San Diego, CA (US); Joan Rey Villarba BUOT, Escondido, CA (US); Kuiwon KANG, San Diego, CA (US)

(21) Appl. No.: 18/607,332

(22) Filed: Mar. 15, 2024

(51) Int. Cl. H05K 3/02; H01L 23/498; H05K 1/09; H05K 1/11; H05K 3/00; H05K 3/42

(52) U.S. Cl. CPC H05K 3/022; H01L 23/49822; H05K 1/09; H05K 1/115; H05K 3/0047; H05K 3/427; H05K 2201/0209; H05K 2201/0358

(57) ABSTRACT

In an aspect, an IC device may include a substrate including a copper clad laminate (CCL) core and a glass block at least partially embedded in the CCL core; a first metallization structure including a plurality of first dielectric layers; a plurality of first metal layers; and a plurality of first vias configured to couple adjacent metal layers of the plurality of first metal layers through the plurality of first dielectric layers; and a second metallization structure comprising a plurality of second dielectric layers, a plurality of second metal layers and a plurality of second vias, wherein the second metallization structure is disposed on a second side of the substrate opposite the first metallization structure disposed on a first side of the substrate.

### TECHNICAL FIELD

The present disclosure generally relates to semiconductor devices including an integrated circuit (IC) package, and more particularly, but not exclusively, to devices including a buried glass core in a package substrate and fabrication techniques thereof.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a package substrate or interposer coupled to one or more IC chips in an IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth™, and other communications), and the like. As used herein the term “function block” should not be construed to be power or signal lines, traces, conductors, pads, etc. that merely function to transmit an electrical voltage and/or current.

As designs become more complex, challenges have arisen in providing high yields during fabrication and final integration into end devices, such as mounting/electrically coupling dies, package, interposers, surface mount technology (SMT) devices, SOC devices, motherboards/printed circuit boards (PCBs) and the like. In some substrate technologies, glass core substrates have been developed for reducing substrate and Silicon coefficient of thermal expansion (CTE) mismatch, but technical barriers have been encountered. For example, premade glass panel have holes formed by glass panel suppliers. The glass layer doesn't support patterning processes due to mechanical weakness. Glass panels are easy to break due to whole panel core being glass. Additionally, conventional glass panels have low reliability especially in relation to drop, shock and vibration failures.

Accordingly, there is a need for improved package substrates for semiconductor devices and methods of manufacturing the same to address the deficiencies in conventional designs, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a substrate including a copper clad laminate (CCL) core and a glass block at least partially embedded in the CCL core; a first metallization structure including a plurality of first dielectric layers; a plurality of first metal layers; and a plurality of first vias configured to couple adjacent metal layers of the plurality of first metal layers through the plurality of first dielectric layers; and a second metallization structure comprising a plurality of second dielectric layers, a plurality of second metal layers and a plurality of second vias, wherein the second metallization structure is disposed on a second side of the substrate opposite the first metallization structure disposed on a first side of the substrate.

In an aspect, a method of manufacturing an apparatus comprising a package substrate includes forming a substrate including at least partially embedding a glass block in a copper clad laminate (CCL) core; forming a first metallization structure including a plurality of first dielectric layers; a plurality of first metal layers; and a plurality of first vias configured to couple adjacent metal layers of the plurality of first metal layers through the plurality of first dielectric layers; and forming a second metallization structure comprising a plurality of second dielectric layers, a plurality of second metal layers and a plurality of second vias configured to couple adjacent metal layers of the plurality of second metal layers through the plurality of second dielectric layers, wherein the second metallization structure is disposed on a second side of the substrate opposite the first metallization structure disposed on a first side of the substrate.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is a partial cross-sectional view of an apparatus including an integrated circuit (IC) package, according to aspects of the disclosure.

FIG. 2 is a partial plan view of an apparatus including an integrated circuit (IC) package, according to aspects of the disclosure.

FIGS. 3A-3G illustrate structures at various stages of manufacturing a substrate for an IC package, according to aspects of the disclosure.

FIG. 4 illustrates a method for manufacturing a substrate for an IC package, according to aspects of the disclosure.

FIG. 5 illustrates a mobile device, according to aspects of the disclosure.

FIG. 6 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, substantially and the like indicate that the examples provided are not intended to be limited to the precise numerical values or geometric shapes and include normal variations due to manufacturing tolerances and variations, material variations, and other design considerations. Likewise, the terms “same”, “similar” and the like include aspects that may be exactly the same or a close proximate in terms of the numerical values or geometric shapes and include normal variations due to manufacturing tolerances and variations, material variations, and other design considerations. Further, a metallization structure as used herein may function as a redistribution layer (RDL) structure, which may provide for metal interconnects that redistribute the access to different parts of the die and in some aspects may allow for a change in pitch between connectors to allow for easier connection from the die to external components. Additionally, terms such as substrate, package substrate and interposer may be used interchangeably to refer to a structure having one or more metal layers disposed on opposite sides. Also, relative terms such as “small”, “large”, “wide”, “fine”, “narrow”, “wide”, “thick”, “thin”, “high”, “low” and the like should be construed in the context of various design standards, technologies and/or applications. For example, fine line spacing may be construed based on minimum distances between lines for a given design standard and high voltage will depend on a given operating or standard voltage range for a given design. One skilled in the art will readily understand any of these terms used in the context of the disclosure provided herein.

The various aspects disclosed provide improvements to improve package substrates with buried glass cores. In various aspects, a package substrate may include a buried glass core for specific area for CTE mismatch (e.g., die shadow area). As used herein, the terms “buried”, “embedded”, “disposed in”, and the like should not be construed to mean that the entirety of the component or element is enclosed, surrounded, encapsulated, and the like. Instead, each instance should be construed as being at least partially “buried”, “embedded”, “disposed in”, and the like as in some aspects portions may protrude or not be completely enclosed. In some aspects, the buried glass core includes a glass block embedded in a copper clad laminate (CCL) core that can protect the glass block from mechanical stress. In some aspects, the CCL portion can support patterning for electrical connections. The various aspects disclosed improve reliability over conventional pure glass substrates. Since singulation us performed in the CCL portion no glass is exposed at the package substrate side, which prevents mechanical damage during processing and improves the package substrate reliability. Additionally, the various aspects disclosed can use conventional substrate processing/fabrication infrastructure. Further, there is no need for vendor pre-drilling which increases the manufacturing costs and supply chain complexity. In addition to the glass core allowing for CTE to be tunable to minimize CTE mismatch with the Si of the die, the various aspects disclosed provide for stable shrinkage in large form factor devices, a high modulus and dimension stability, high speed signaling and other beneficial aspects which will be appreciated from the following disclosure.

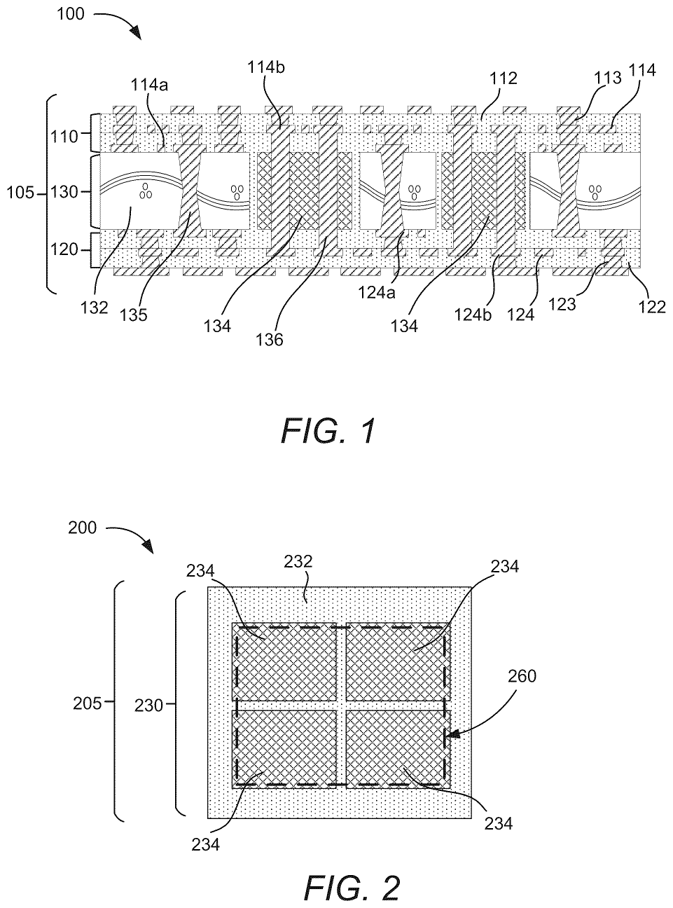

FIG. 1 is a cross-sectional view of an apparatus 100, according to aspects of the disclosure. In some aspects, FIG. 1 is a simplified cross-sectional view of the apparatus 100, and certain details and components of the apparatus 100 may be simplified or omitted in FIG. 1.

In some aspects, as shown in FIG. 1, the apparatus 100 is illustrated as a portion of an IC package and/or a larger apparatus such as a mobile device, server, etc. In some aspects, the apparatus 100 includes a buried glass core substrate 130 including a glass block 134 and a first metallization structure 110. The term “buried glass core substrate” is used herein as a descriptive term for a substrate comprising a copper clad laminate (CCL) core and a glass block at least partially embedded in the CCL core. The first metallization structure 110 includes a plurality of first metal layers 114, a plurality of first dielectric layers 112, a plurality of first vias 113 configured to couple adjacent metal layers 114 of the plurality of first metal layers 114 through the plurality of first dielectric layers 112. buried glass core substrate 130. In some aspects, the first metallization structure 110 may comprise fiberglass impregnated with resin (prepreg), Ajinomoto build-up film (ABF), or a resin coated copper (RCC) build-up film.

The package substrate 105 further may include: a buried glass core substrate 130 including a CCL core 132 including pre-impregnated reinforcement components embedded therein. In some aspects, the buried glass core substrate 130 may include at least one plated through hole (PTH) 135 disposed through the CCL core 132 configured to provide an electrical connection to opposite sides of the CCL core 132. The first metallization structure 110 is disposed on the first side of the buried glass core substrate 130. The second metallization structure 120 is disposed on the second side of the buried glass core substrate 130. In some aspects, at least one TGV 136 is disposed through the glass block. In some aspects, there may be combination of both PTHs 135 and TGVs 136. In some aspects, if there is at least one PTH disposed through the CCL core 132, it can be used to couple to a first metal layer 114a of the first metallization structure 110 disposed on the CCL core 132 on the first side and also in some aspects to a first metal layer 124a of the second metallization structure 120 disposed on the CCL core 132 on the second side. In some aspects, if there is least one TGV 136 disposed through the glass block 134, it can be used to couple to a second metal layer 114b of the first metallization structure 110 on the first side which is not disposed on the glass block 134 and also in some aspects to a second metal layer 124b of the second metallization structure 120 not disposed on the glass block 134 on the second side. In some aspects, buried glass core substrate 130 combination of both PTHs 135 and TGVs 136.

The second metallization structure 120 may include a plurality of second dielectric layers 122, a plurality of second metal layers 124 and a plurality of second vias 123. The second metallization structure 120 is disposed on a second side of the buried glass core substrate 130 opposite the first metallization structure 110. The second metallization structure 120 may include fiberglass impregnated with resin (prepreg), Ajinomoto build-up film (ABF), or a resin coated copper (RCC) build-up film.

In some aspects, the buried glass core substrate 130 further comprises a plurality of glass blocks and each glass block 134 is one of the plurality of glass blocks.

In some aspects, the metal layers and vias of the first metallization structure 110, the second metallization structure 120, PTH 135 and TGV 136 of the buried glass core substrate 130 may comprise any high conductive material, such as, copper (Cu), aluminum (AL), silver (Ag), gold (Au) titanium (Ti), nickel (Ni), tin (Sn), lead (Pb), alloys or combinations thereof.

FIG. 2 is a plan view of an apparatus 200, according to aspects of the disclosure. In some aspects, FIG. 2 is a simplified view of the apparatus 200, and certain details and components of the apparatus 200 may be simplified or omitted in FIG. 2. Further, it will be appreciated that FIG. 2 may be similar to apparatus 100 of FIG. 1, so many elements, such as the metallization layers will not be illustrated to reduce complexity.

In some aspects, as shown in FIG. 2 the apparatus 200 may be a portion of an IC package and/or a larger apparatus such as a mobile device, server, etc. In some aspects, the apparatus 200 includes a buried glass core substrate 230 including a plurality of glass blocks 234 and each glass block 234 is one of the plurality of glass blocks 234. The package substrate 205 may include a buried glass core substrate 230 designed for a specific area for CTE mismatch (e.g., die 260 shadow area). The die 260 is illustrated as a dashed perimeter to aid in the illustration of the various aspects disclosed. In some aspects, each glass block 234 is part of an arrangement of a plurality of glass blocks 234 and the arrangement is a same size or larger than the die 260 and the arrangement is disposed under the die 260. Each glass block 234 and the plurality of glass blocks is enclosed within a perimeter of the CCL core 232. It will be appreciated, depending on the size of the die 260 and other design considerations, only one glass block 234 may be used per die. Additionally, it will be appreciated that size (area) of each glass block 234 may be the same or may be different and the number of glass blocks 234 per buried glass core substrate 230 is not limited to any specific number or arrangement of glass blocks 234.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

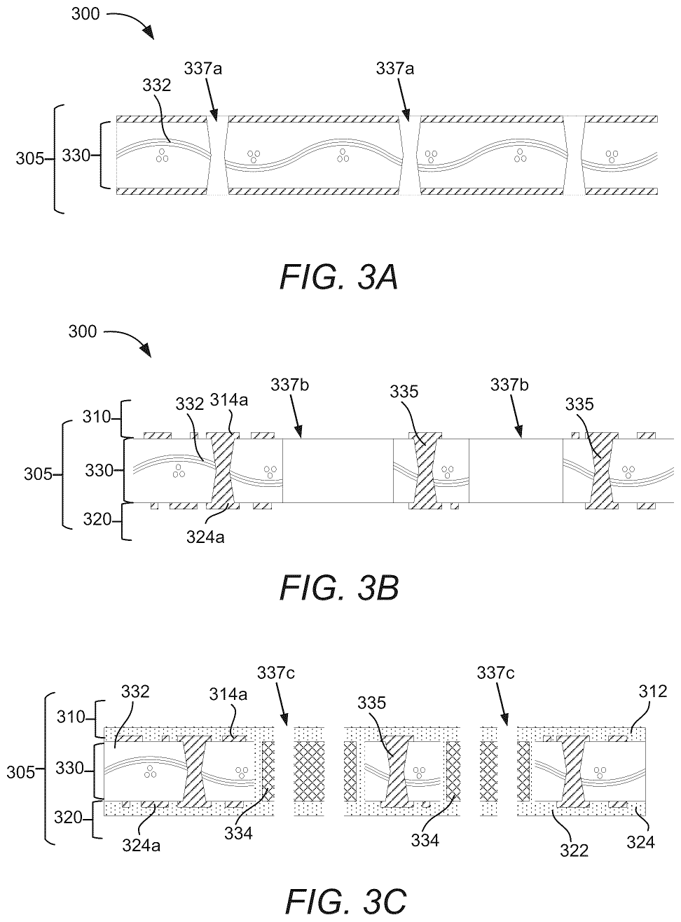

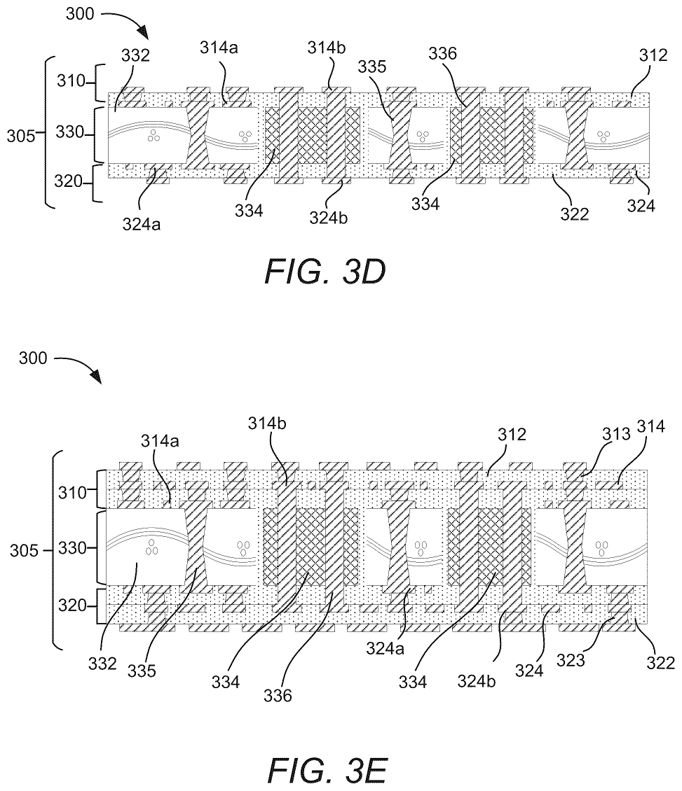

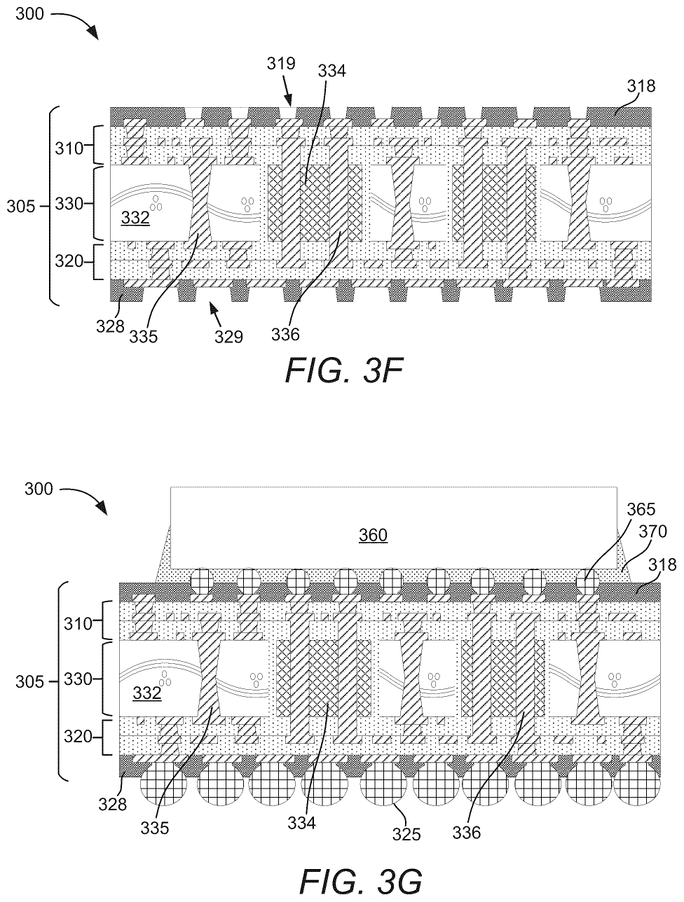

FIGS. 3A-3G illustrate structures at various stages of manufacturing/fabricating an apparatus 300, which is similar to the example apparatus 100 in FIG. 1 as a non-limiting example, according to aspects of the disclosure. Many of the elements illustrated in FIGS. 3A-3G are the same or similar to those of FIG. 1, and therefore detailed description thereof may be omitted.

As shown in FIG. 3A, the fabrication process for apparatus 300 may begin with a package substrate 305 being partially formed including a buried glass core substrate 330. At this stage of the fabrication process, one or more cavities 337a (e.g., inner layer via hole (IVH), buried layer via hole (BVH)) are formed in the CCL core 332 by drilling or any other suitable process. The package substrate 305 can be formed using conventional processes (build-up process). To simplify the illustrations and eliminate unnecessary repetition, the following process stages will not provide details of all conventional processing operations. Additionally, since the described elements are similar to corresponding elements described in the foregoing, a detailed description of each will not be provided.

In FIG. 3B, the fabrication process for apparatus 300 may continue with the package substrate 305 being partially formed including the buried glass core substrate 330 comprising the CCL core 332, with the cavities filled. At this stage of the fabrication process, one or more plated through holes (PTHs) 335 are formed in the CCL core 332, by filling the previously formed cavities. Additionally, a first metal layer 314a of a first metallization structure 310 and a first metal layer 324a of a second metallization structure 320 on opposite sides of the CCL core 332, are patterned and etched to form the desired metal structures, traces, etc. It will be appreciated that the first metal layers 314a and 324a are formed from the outer metal layers of the CCL core 332. The PTHs 335 couple portions of the first metal layer 314a and the first metal layer 324a. Additionally, one or more glass block cavities 337b are formed in the CCL core 332.

In FIG. 3C, the fabrication process for apparatus 300 may continue with the package substrate 305 being partially formed. The package substrate 305 includes the buried glass core substrate 330 comprising the CCL core 332, one or more PTHs 335, and the first metal layers 314a and 324a. At this stage of the fabrication process, one or more glass blocks 334 are embedded in the CCL core 332, in the previously formed glass block cavities. Additionally, the build-up process is started for fabricating the first metallization structure 310 and the second metallization structure 320. The first metallization structure 310 includes an initial portion of a plurality of first metal layers 314 and a plurality of first dielectric layers 312. The second metallization structure 320 includes an initial portion of a plurality of second metal layers 324 and a plurality of second dielectric layers 322. The initial portions of the first and second dielectric layers (312 and 322) are also deposited over the glass blocks 334 and fill in any gaps in the previously formed glass block cavity. After the initial portions of the first and second dielectric layers (312 and 322) are deposited a drilling process is performed to form buried via holes (BVHs) 337c in the glass blocks 334. In the various aspects disclosed, the drilling process may include drilling the dielectric material and glass block together (e.g., a dielectric and glass one time drilling process).

In FIG. 3D, the fabrication process for apparatus 300 may continue with the package substrate 305 being partially formed. The package substrate 305 includes the buried glass core substrate 330 comprising the CCL core 332, one or more PTHs 335 and one or more glass blocks 334. The first metal layers 314a and 324a, and the initial portions of the first and second dielectric layers (312 and 322) are also formed. At this stage of the fabrication process, first metallization structure 310 has additional portions formed of the plurality of first metal layers 314, the plurality of first dielectric layers 312 and the plurality of first vias 313. Specifically, the second metal layer 314b is formed. The second metallization structure 320 also has additional portions formed of the plurality of second metal layers 324, the plurality of second dielectric layers 322 and the plurality of second vias 323. Specifically, the second metal layer 324b is formed. Additionally, the through glass vias (TGVs) 336 are formed by filling the previously formed BVHs in the glass blocks 334. The TGVs are coupled to the second metal layers on both sides of the buried glass core substrate 330. In some aspects, a Semi-Additive Process (SAP) process is used for filling BVHs in the glass block and patterning the various build-up layers.

In FIG. 3E, the fabrication process for apparatus 300 may continue with the package substrate 305 being partially formed. The package substrate 305 includes the buried glass core substrate 330 comprising the CCL core 332, one or more PTHs 335 and one or more glass blocks 334 with TGVs 336. The first metal layers 314a and 324a, and the initial portions of the first and second dielectric layers (312 and 322) are also formed. At this stage of the fabrication process, the first metallization structure 310 has additional top portions formed (outer most layers from the buried glass core substrate 330) of the plurality of first metal layers 314, the plurality of first dielectric layers 312 and the plurality of first vias 313. The second metallization structure 320 also has additional bottom portions formed (outer most layers from the buried glass core substrate 330) of the plurality of second metal layers 324, the plurality of second dielectric layers 322 and the plurality of second vias 323. It will be appreciated that the outer metal layers on both the first metallization structure 310 and the second metallization structure 320 may include pads for forming external connections. In some aspects, the first metallization structure 310 and the second metallization structure 320 may be formed by repeated build-up processing including in some aspects the SAP process, discussed above.

In FIG. 3F, the fabrication process for apparatus 300 may continue with the package substrate 305 being substantially formed. The package substrate 305 includes the buried glass core substrate 330 comprising the CCL core 332, one or more PTHs 335 and one or more glass blocks 334 with TGVs 336. The first metallization structure 310 and the second metallization structure 320 are also formed. At this stage, a top solder resist (SR) layer 318 is deposited on the top of the first metallization structure 310. A plurality of solder resist openings (SROs) 319 is formed in the SR layer 318 to allow for the die attach process in subsequent processing stages. A bottom solder resist (SR) layer 328 is also deposited on the bottom of the second metallization structure 320. A plurality of bottom solder resist openings (SROs) 329 is formed in the bottom SR layer 328 to allow for the ball attach process in subsequent processing stages.

In FIG. 3G, the fabrication process for apparatus 300 may continue with the package substrate 305 being substantially formed. The package substrate 305 includes the buried glass core substrate 330 comprising the CCL core 332, one or more PTHs 335 and one or more glass blocks 334 with TGVs 336. The first metallization structure 310 and the second metallization structure 320 are also formed. The top solder resist (SR) layer 318 is deposited on the top of the first metallization structure 310. A bottom solder resist (SR) layer 328 is deposited on the bottom of the second metallization structure 320. At this stage of the fabrication process a plurality of package connectors 325 (e.g., solder bumps, BGA, copper pillar bumps, pins or any suitable connector technology), coupled to the second metallization structure 320, are formed (e.g., ball-drop on pads of the second metallization structure 320 through the prior SROs or any conventional process). The plurality of package connectors 325 can be configured to couple to an external component, such as a printed circuit board (PCB), additional packages, and the like. Accordingly, it will be appreciated that the package connectors 325 may vary depending on the device design. Additionally, at this stage of the fabrication process a die 360 is disposed on top of the first metallization structure 310 and electrically coupled to the first metallization structure 310 by a plurality of die connectors 365 (e.g., die bumps, solder, pins, pillars, or any suitable connector design) using conventional processes for a given connector technology. In some aspects, a die underfill material 370 may be disposed between the die 360 and the first metallization structure 310 and encapsulate the die connectors 365. In some aspects, the die underfill material 370 comprises an organic material.

It will be appreciated that additional processing can be performed using known techniques to form and attach additional structures (e.g., a mold compound, lid, etc. may be used to encapsulate the die). Additional dies may be coupled to the package substrate or arranged in a stacked structure. Further, the various aspects disclosed may include additional substrates that may be used to interface to a printed circuit board (PCB) or other external device. Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

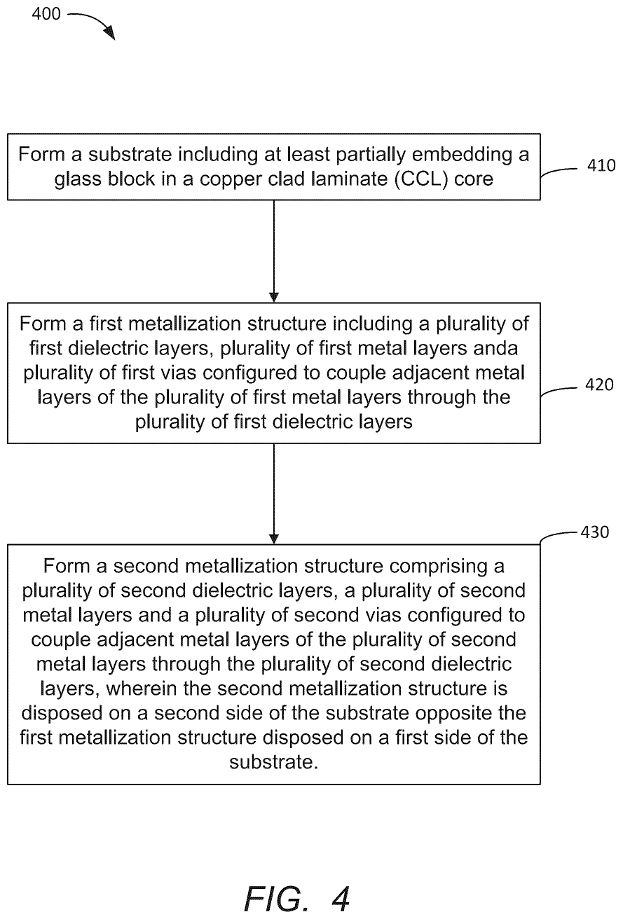

FIG. 4 illustrates a process 400 for manufacturing/fabricating an apparatus comprising a package substrate (such as an IC package incorporating the features of any of the example apparatuses 100, 200 or 300), according to aspects of the disclosure. In some aspects, FIGS. 3A-3G may depict the substrate at different stages of manufacturing according to the process 400. It will be appreciated from the foregoing that there are various methods for fabricating devices as disclosed herein.

At operation 410, the process 400 includes forming a buried glass core substrate (e.g., buried glass core substrate 130, 230 or 230) including at least partially embedding a glass block (e.g., 134, 234, or 334) in a copper clad laminate (CCL) core (e.g., 132, 232, or 332).

At operation 420, the process 400 includes forming a first metallization structure (e.g., (e.g., 110 or 310). The first metallization structure (e.g., 110 or 310) includes a plurality of first dielectric layers (e.g., 112 or 312); a plurality of first metal layers (e.g., 114 or 314); and a plurality of first vias (e.g., 113 or 313) configured to couple adjacent metal layers of the plurality of first metal layers through the plurality of first dielectric layers.

At operation 430, the process 400 includes forming a second metallization structure (e.g., 120 or 320) comprising a plurality of second dielectric layers (e.g., 122 or 322), a plurality of second metal layers (e.g., 124 or 324) and a plurality of second vias (e.g., 123 or 323) configured to couple adjacent metal layers of the plurality of second metal layers through the plurality of second dielectric layers, wherein the second metallization structure is disposed on a second side of the buried glass core substrate opposite the first metallization structure disposed on a first side of the buried glass core substrate.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

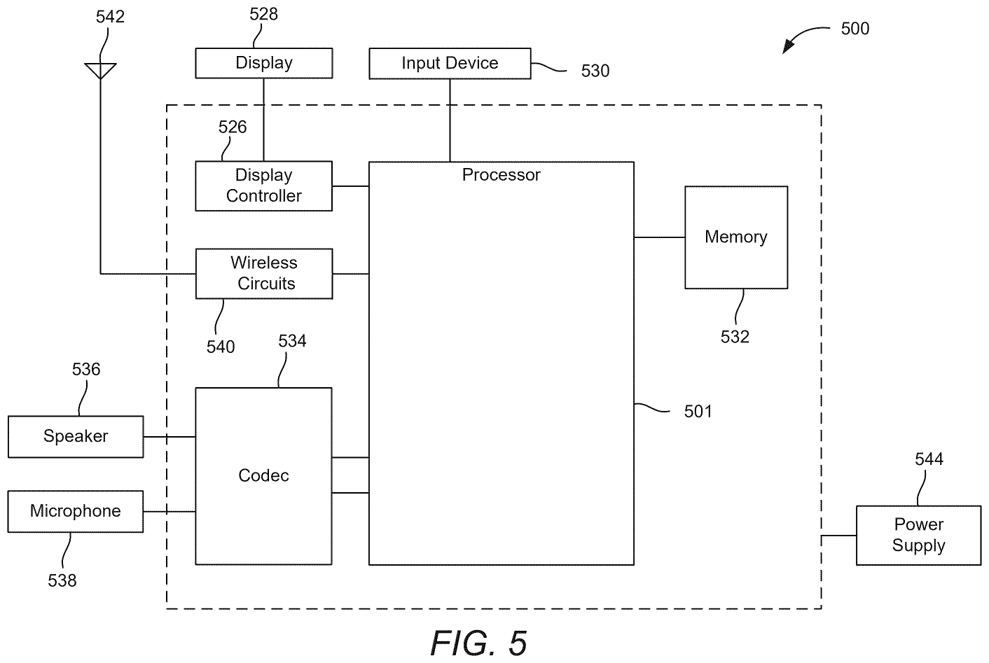

FIG. 5 illustrates a mobile device 500, according to aspects of the disclosure. In some aspects, the mobile device 500 may be implemented by including one or more IC devices including package substrates with buried glass substrate cores as disclosed herein.

In some aspects, mobile device 500 may be configured as a wireless communication device. As shown, mobile device 500 includes processor 501. Processor 501 may be communicatively coupled to memory 532 over a link, which may be a die-to-die or chip-to-chip link. Mobile device 500 also includes display 528 and display controller 526, with display controller 526 coupled to processor 501 and to display 528. The mobile device 500 may include input device 530 (e.g., physical, or virtual keyboard), power supply 544 (e.g., battery), speaker 536, microphone 538, and wireless antenna 542. In some aspects, the power supply 544 may directly or indirectly provide the supply voltage for operating some or all of the components of the mobile device 500.

In some aspects, FIG. 5 may include coder/decoder (CODEC) 534 (e.g., an audio and/or voice CODEC) coupled to processor 501; speaker 536 and microphone 538 coupled to CODEC 534; and wireless circuits 540 (which may include a modem, RF circuitry, filters, etc.) coupled to wireless antenna 542 and to processor 501.

In some aspects, one or more of processor 501 (e.g., SoCs, application processor (AP), central processing unit (CPU), digital signal processor (DSP), etc.), display controller 526, memory 532, CODEC 534, and wireless circuits 540 (e.g., baseband interface) including IC devices that are packaged as IC packages and including package substrates with buried glass substrate cores according to the various aspects described in this disclosure.

It should be noted that although FIG. 5 depicts a mobile device 500, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

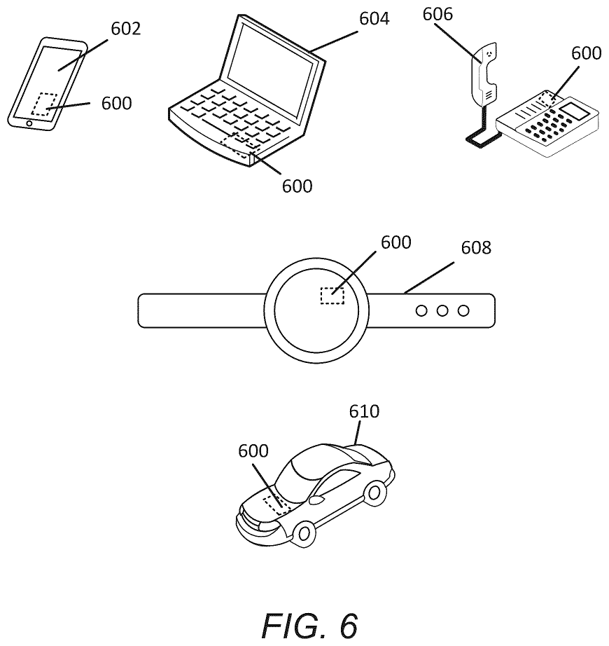

FIG. 6 illustrates various electronic devices that may be integrated with any of the aforementioned devices, semiconductor devices, integrated circuit (IC) packages, integrated circuit (IC) devices, electronic components, interposer packages, package-on-package (POP), System in Package (SiP), or System on Chip (SoC). For example, a mobile phone device 602, a laptop computer device 604, a fixed location terminal device 606, a wearable device 608, or automotive vehicle 610 may include a semiconductor device 600 (e.g., apparatus 100, 200 or 300 including package substrates 105, 205 or 305, respectively) as described herein. The devices 602, 604, 606 and 608 and the vehicle 610 illustrated in FIG. 6 are merely exemplary. Other apparatuses or devices may also feature the semiconductor device 600 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 6 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1, 2, 3A-3G, and 4-6 may be rearranged and/or combined into a single component, process, feature, or function or incorporated in several components, processes, or functions. Additional elements, components, processes, and/or functions may also be added without departing from the disclosure. In some implementations, FIGS. 1, 2, 3A-3G, and 4-6 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising a package substrate, the package substrate comprising: a substrate including a copper clad laminate (CCL) core and a glass block at least partially embedded in the CCL core; a first metallization structure including a plurality of first dielectric layers; a plurality of first metal layers; and a plurality of first vias configured to couple adjacent metal layers of the plurality of first metal layers through the plurality of first dielectric layers; and a second metallization structure comprising a plurality of second dielectric layers, a plurality of second metal layers and a plurality of second vias, wherein the second metallization structure is disposed on a second side of the substrate opposite the first metallization structure disposed on a first side of the substrate.

Clause 2. The apparatus of clause 1, wherein the substrate further comprises a plurality of glass blocks and the glass block is one of the plurality of glass blocks.

Clause 3. The apparatus of any of clauses 1 to 2, wherein the CCL core and the glass block have a same thickness.

Clause 4. The apparatus of clause 3, wherein the substrate has a thickness in a range of 40 micrometers (um) to 800 (um).

Clause 5. The apparatus of any of clauses 3 to 4, wherein the glass block is enclosed within a perimeter of the CCL core.

Clause 6. The apparatus of any of clauses 1 to 5, wherein a first metal layer of the first metallization layer is disposed on the CCL core.

Clause 7. The apparatus of clause 6, wherein the first metal layer of the first metallization layer is not disposed on the glass block.

Clause 8. The apparatus of any of clauses 1 to 7, wherein the first metallization structure comprises: fiberglass impregnated with resin (prepreg), Ajinomoto build-up film (ABF), or a resin coated copper (RCC) build-up film, and wherein the second metallization structure comprises fiberglass impregnated with resin (prepreg), Ajinomoto build-up film (ABF), or a resin coated copper (RCC) build-up film.

Clause 9. The apparatus of any of clauses 1 to 8, wherein the substrate comprises: at least one plated through hole (PTH) disposed through the CCL core configured to provide an electrical connection to opposite sides of the CCL core, at least one through glass via (TGV) disposed through the glass block or a combination of both.

Clause 10. The apparatus of clause 9, wherein the at least one PTH disposed through the CCL core is coupled to a first metal layer disposed on the CCL core, or the at least one TGV disposed through the glass block extends to and is coupled to a second metal layer not in contact with the glass block, or a combination of both.

Clause 11. The apparatus of any of clauses 1 to 10, wherein the apparatus further comprises: a die disposed on and electrically coupled to the package substrate.

Clause 12. The apparatus of clause 11, wherein the glass block is a same size or larger than the die and is disposed under the die.

Clause 13. The apparatus of clause 12, wherein the glass block is part of an arrangement of a plurality of glass blocks and the arrangement is a same size or larger than the die and the arrangement is disposed under the die.

Clause 14. The apparatus of any of clauses 1 to 13, wherein the apparatus comprises at least one of: a music player; a video player; an entertainment unit; a navigation device; a communications device; a mobile device; a mobile phone; a smartphone; a personal digital assistant; a fixed location terminal; a tablet computer; a computer; a wearable device; a laptop computer; a server; an internet of things (IoT) device; or an automotive vehicle device.

Clause 15. A method of manufacturing an apparatus comprising a package substrate, the method comprising: forming a substrate including at least partially embedding a glass block in a copper clad laminate (CCL) core; forming a first metallization structure including a plurality of first dielectric layers; a plurality of first metal layers; and a plurality of first vias configured to couple adjacent metal layers of the plurality of first metal layers through the plurality of first dielectric layers; and forming a second metallization structure comprising a plurality of second dielectric layers, a plurality of second metal layers and a plurality of second vias configured to couple adjacent metal layers of the plurality of second metal layers through the plurality of second dielectric layers, wherein the second metallization structure is disposed on a second side of the substrate opposite the first metallization structure disposed on a first side of the substrate.

Clause 16. The method of clause 15, wherein forming the substrate comprises: forming at least one plated through hole (PTH) disposed through the CCL core, forming at least one through glass via (TGV) disposed through the glass block or a combination of both.

Clause 17. The method of clause 16, wherein the at least one PTH disposed through the CCL core is coupled to a first metal layer disposed on the CCL core, or the at least one TGV disposed through the glass block is coupled to a second metal layer not in contact with the glass block, or a combination of both.

Clause 18. The method of any of clauses 16 to 17, wherein forming the at least one through glass via (TGV) disposed through the glass block comprises: depositing a first dielectric layer on the first side of the glass block; depositing a second dielectric layer on the second side of the glass block; and drilling through the first dielectric layer, glass block, and the second dielectric layer.

Clause 19. The method of any of clauses 15 to 18, further comprising: electrically coupling a die to the package substrate, wherein the die is disposed on the package substrate and wherein the glass block is disposed under the die and is a same size or larger than the die.

Clause 20. The method of any of clauses 15 to 19, further comprising: electrically coupling a die to the package substrate, wherein the die is disposed on the package substrate and wherein the glass block is part of an arrangement of a plurality of glass blocks and the arrangement is a same size or larger than the die, and wherein the arrangement is disposed under the die.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus, comprising a package substrate, the package substrate comprising:
a substrate including a copper clad laminate (CCL) core and a glass block at least partially embedded in the CCL core;
a first metallization structure including a plurality of first dielectric layers; a plurality of first metal layers; and a plurality of first vias configured to couple adjacent metal layers of the plurality of first metal layers through the plurality of first dielectric layers; and
a second metallization structure comprising a plurality of second dielectric layers, a plurality of second metal layers and a plurality of second vias,
wherein the second metallization structure is disposed on a second side of the substrate opposite the first metallization structure disposed on a first side of the substrate.

2. The apparatus of claim 1, wherein the substrate further comprises a plurality of glass blocks and the glass block is one of the plurality of glass blocks.

3. The apparatus of claim 1, wherein the CCL core and the glass block have a same thickness.

4. The apparatus of claim 3, wherein the substrate has a thickness in a range of 40 micrometers (um) to 800 (um).

5. The apparatus of claim 3, wherein the glass block is enclosed within a perimeter of the CCL core.

6. The apparatus of claim 1, wherein a first metal layer of the first metallization layer is disposed on the CCL core.

7. The apparatus of claim 6, wherein the first metal layer of the first metallization layer is not disposed on the glass block.

8. The apparatus of claim 1, wherein the first metallization structure comprises:
fiberglass impregnated with resin (prepreg), Ajinomoto build-up film (ABF), or a resin coated copper (RCC) build-up film, and
wherein the second metallization structure comprises fiberglass impregnated with resin (prepreg), Ajinomoto build-up film (ABF), or a resin coated copper (RCC) build-up film.

9. The apparatus of claim 1, wherein the substrate comprises:
at least one plated through hole (PTH) disposed through the CCL core configured to provide an electrical connection to opposite sides of the CCL core, at least one through glass via (TGV) disposed through the glass block or a combination of both.

10. The apparatus of claim 9, wherein the at least one PTH disposed through the CCL core is coupled to a first metal layer disposed on the CCL core, or the at least one TGV disposed through the glass block extends to and is coupled to a second metal layer not in contact with the glass block, or a combination of both.

11. The apparatus of claim 1, wherein the apparatus further comprises:
a die disposed on and electrically coupled to the package substrate.

12. The apparatus of claim 11, wherein the glass block is a same size or larger than the die and is disposed under the die.

13. The apparatus of claim 12, wherein the glass block is part of an arrangement of a plurality of glass blocks and the arrangement is a same size or larger than the die and the arrangement is disposed under the die.

14. The apparatus of claim 1, wherein the apparatus comprises at least one of: a music player; a video player; an entertainment unit; a navigation device; a communications device; a mobile device; a mobile phone; a smartphone; a personal digital assistant; a fixed location terminal; a tablet computer; a computer; a wearable device; a laptop computer; a server; an internet of things (IoT) device; or an automotive vehicle device.

15. A method of manufacturing an apparatus comprising a package substrate, the method comprising:
forming a substrate including at least partially embedding a glass block in a copper clad laminate (CCL) core;
forming a first metallization structure including a plurality of first dielectric layers; a plurality of first metal layers; and a plurality of first vias configured to couple adjacent metal layers of the plurality of first metal layers through the plurality of first dielectric layers; and
forming a second metallization structure comprising a plurality of second dielectric layers, a plurality of second metal layers and a plurality of second vias configured to couple adjacent metal layers of the plurality of second metal layers through the plurality of second dielectric layers,
wherein the second metallization structure is disposed on a second side of the substrate opposite the first metallization structure disposed on a first side of the substrate.

16. The method of claim 15, wherein forming the substrate comprises:
forming at least one plated through hole (PTH) disposed through the CCL core, forming at least one through glass via (TGV) disposed through the glass block or a combination of both.

17. The method of claim 16, wherein the at least one PTH disposed through the CCL core is coupled to a first metal layer disposed on the CCL core, or the at least one TGV disposed through the glass block is coupled to a second metal layer not in contact with the glass block, or a combination of both.

18. The method of claim 16, wherein forming the at least one through glass via (TGV) disposed through the glass block comprises:
depositing a first dielectric layer on the first side of the glass block;
depositing a second dielectric layer on the second side of the glass block; and
drilling through the first dielectric layer, glass block, and the second dielectric layer.

19. The method of claim 15, further comprising:
electrically coupling a die to the package substrate, wherein the die is disposed on the package substrate and wherein the glass block is disposed under the die and is a same size or larger than the die.

20. The method of claim 15, further comprising:
electrically coupling a die to the package substrate, wherein the die is disposed on the package substrate and wherein the glass block is part of an arrangement of a plurality of glass blocks and the arrangement is a same size or larger than the die, and wherein the arrangement is disposed under the die.
